(19) United States
(12) Patent Application Publication
(10) Pub. No.: US 2026/0020486 A1
(43) Pub. Date: Jan. 15, 2026

(54) DISPLAY DEVICE, METHOD OF MANUFACTURING THE SAME, AND ELECTRONIC DEVICE INCLUDING THE SAME

(71) Applicant: Samsung Display Co., Ltd., Yongin-Si (KR)

(72) Inventor: GEUNWOO YUG, Yongin-si (KR)

(21) Appl. No.: 19/172,719

(22) Filed: Apr. 8, 2025

(30) Foreign Application Priority Data
Jul. 11, 2024 (KR) 10-2024-0091773

(51) Int. Cl. H10K 59/80; H10K 59/12

(52) U.S. Cl. CPC H10K 59/8791; H10K 59/1201; H10K 59/873

(57) ABSTRACT

A display device includes: a substrate having an edge including a first side extending in a first direction, a second side extending in a second direction intersecting the first direction, and a curved portion which connects the first side and the second side and has a predetermined curvature in a plan view; a light-emitting element disposed on the substrate; and a polarization layer disposed on the light-emitting element and including a polarization film disposed on the light-emitting element, a first functional layer disposed between the light-emitting element and the polarization film, and a second functional layer disposed on the polarization film. In the curved portion in the plan view, the polarization film has a side surface which is recessed from a side surface of the polarization layer, and the first functional layer and the second functional layer cover the recessed side surface of the polarization film.

### CROSS-REFERENCE TO RELATED APPLICATION

This application claims priority under 35 USC § 119 to Korean Patent Application No. 10-2024-0091773, filed on Jul. 11, 2024, in the Korean Intellectual Property Office, the content of which is herein incorporated by reference in its entirety.

### BACKGROUND

### 1. Field

The present disclosure relates generally to a display device. More particularly, the present disclosure relates to a display device, a method of manufacturing the same, and an electronic device including the same.

### 2. Description of the Related Art

With the development of information technology, the importance of a display device, which is a connection medium between a user and information, has been highlighted. For example, the use of display devices such as liquid crystal display (“LCD”) device, organic light-emitting diode (“OLED”) display device, plasma display panel (“PDP”) device, quantum dot display device or the like is increasing.

When light incident from the outside is reflected from lines, electrodes, etc. included in the display device, the display quality of the display device may be degraded by the reflected light. To reduce such external light reflection, the display device may include a polarization layer.

### SUMMARY

Embodiments provide a display device including a polarization layer with improved reliability.

Embodiments provide a method of manufacturing the display device.

Embodiments provide an electronic device including the display device.

A display device according to an embodiment of the present disclosure includes: a substrate having an edge including a first side extending in a first direction, a second side extending in a second direction intersecting the first direction, and a curved portion which connects the first side and the second side and has a predetermined curvature in a plan view; a light-emitting element disposed on the substrate; and a polarization layer disposed on the light-emitting element and including a polarization film disposed on the light-emitting element and having a side surface which is recessed from a side surface of the polarization layer in the curved portion in the plan view, a first functional layer disposed between the light-emitting element and the polarization film and covering the recessed side surface of the polarization film in the curved portion in the plan view, and a second functional layer disposed on the polarization film, covering the recessed side surface of the polarization film, and contacting the first functional layer in the curved portion in the plan view.

In an embodiment, the polarization film may include a polyvinyl alcohol. Each of the first functional layer and the second functional layer may include a tri-acetyl cellulose.

In an embodiment, each of the first side and the second side may extend in a substantially straight line.

In an embodiment, in the first side and the second side, a side surface of the first functional layer, a side surface of the polarization film, and a side surface of the second functional layer may be substantially aligned along a thickness direction of the substrate in the plan view.

In an embodiment, in the first side and the second side, the first functional layer may be spaced apart from the second functional layer.

A method of manufacturing a display device according to an embodiment of the present disclosure includes: forming a light-emitting element on a mother substrate including a cell area and a dummy area surrounding the cell area, the light-emitting element overlapping the cell area; forming a preliminary polarization layer overlapping the cell area and the dummy area on the light-emitting element and including a first preliminary functional layer, a preliminary polarization film, and a second preliminary functional layer which are sequentially stacked; irradiating a first laser along edges of the cell area toward the mother substrate to form a substrate by removing a portion of the mother substrate and a portion of the preliminary polarization layer in the dummy area; and irradiating a second laser along a first edge of the substrate having a curved shape to form a polarization film having a recessed side surface by deforming the preliminary polarization film in the first edge of the substrate in a plan view and form a first functional layer and a second function layer covering the recessed side surface by deforming the first preliminary functional layer and the second preliminary functional layer in the first edge of the substrate in the plan view.

In an embodiment, a first depth of focus of the first laser may be formed at the mother substrate.

In an embodiment, the portion of the mother substrate and the portion of the preliminary polarization layer may be simultaneously cut by the first laser.

In an embodiment, the preliminary polarization film, the first preliminary functional layer, and the second preliminary functional layer may be deformed by thermal energy provided by the second laser.

In an embodiment, in the deforming the preliminary polarization film, the first preliminary functional layer, and the second preliminary functional layer, the preliminary polarization film may shrink, and each of the first preliminary functional layer and the second preliminary functional layer may expand.

In an embodiment, the substrate and the preliminary polarization layer may not be cut by the second laser.

In an embodiment, a second depth of focus of the second laser may be different from a first depth of focus of the first laser.

In an embodiment, the second depth of focus of the second laser may be longer than the first depth of focus of the first laser.

In an embodiment, the second depth of focus of the second laser may be shorter than the first depth of focus of the first laser.

In an embodiment, a distance between the first depth of focus and the second depth of focus may be about 500 micrometers to about 2 millimeters.

In an embodiment, a second depth of focus of the second laser may be formed under the substrate.

In an embodiment, a distance between the second depth of focus and a lower surface of the first preliminary functional layer may be about 500 micrometers to about 2 millimeters.

In an embodiment, in a second edge of the substrate having a straight line shape in the plan view, a side surface of the first functional layer, a side surface of the polarization film, and a side surface of the second functional layer may be substantially aligned along a line extending in a thickness direction of the substrate.

In an embodiment, in the second edge of the substrate in the plan view, the first functional layer may be spaced apart from the second functional layer.

An electronic device according to an embodiment of the present disclosure includes: a display device including a light-emitting element; and a power supply configured to provide power to the display device. The display device includes: a substrate having an edge including a first side extending in a first direction, a second side extending in a second direction intersecting the first direction, and a curved portion which connects the first side and the second side and has a predetermined curvature in a plan view; the light-emitting element disposed on the substrate; and a polarization layer disposed on the light-emitting element and including a polarization film disposed on the light-emitting element and having a side surface which is recessed from a side surface of the polarization layer in the curved portion in the plan view, a first functional layer disposed between the light-emitting element and the polarization film and covering the recessed side surface of the polarization film in the curved portion in the plan view, and a second functional layer disposed on the polarization film, covering the recessed side surface of the polarization film, and contacting the first functional layer in the curved portion in the plan view.

A display device according to an embodiment of the present disclosure may include a polarization layer including a polarization film having a recessed side surface in an edge of the substrate having a curved shape in a plan view, a first functional layer disposed under the polarization film, and a second functional layer disposed on the polarization film. The first functional layer and the second functional layer may cover the recessed side surface of the polarization film in the edge of the substrate having a curved shape in the plan view.

That is, in the edge of the substrate having a curved shape in the plan view, the recessed side surface of the polarization film may be sealed by the first functional layer and the second functional layer. Accordingly, the first functional layer and the second functional layer may prevent moisture from penetrating into the recessed side surface of the polarization film. As a result, defects of the polarization layer due to moisture may be suppressed, and the reliability of the polarization layer may be improved.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment of the present disclosure.

FIG. 2 is a view illustrating a bent shape of the display device of FIG. 1.

FIG. 3 is a cross-sectional view taken along line I-I′ of FIG. 1.

FIG. 4 is a plan view illustrating the display device of FIG. 1.

FIG. 5 is a cross-sectional view taken along line II-II′ of FIG. 4.

FIG. 6 is a cross-sectional view taken along line III-III′ of FIG. 4.

FIGS. 7, 8, 9, 10, 11, 12, 13, 14, 15, 16, 17, and 18 are views illustrating a method of manufacturing a display device according to an embodiment of the present disclosure.

FIG. 19 is a block diagram illustrating an electronic device according to an embodiment of the present disclosure.

FIG. 20 is a view illustrating an example in which the electronic device of FIG. 19 is implemented as a smart phone.

### DETAILED DESCRIPTION OF THE EMBODIMENTS

Hereinafter, embodiments of the present disclosure will be described in detail with reference to the accompanying drawings. The same reference numerals are used for the same components in the drawings, and redundant descriptions of the same components will be omitted.

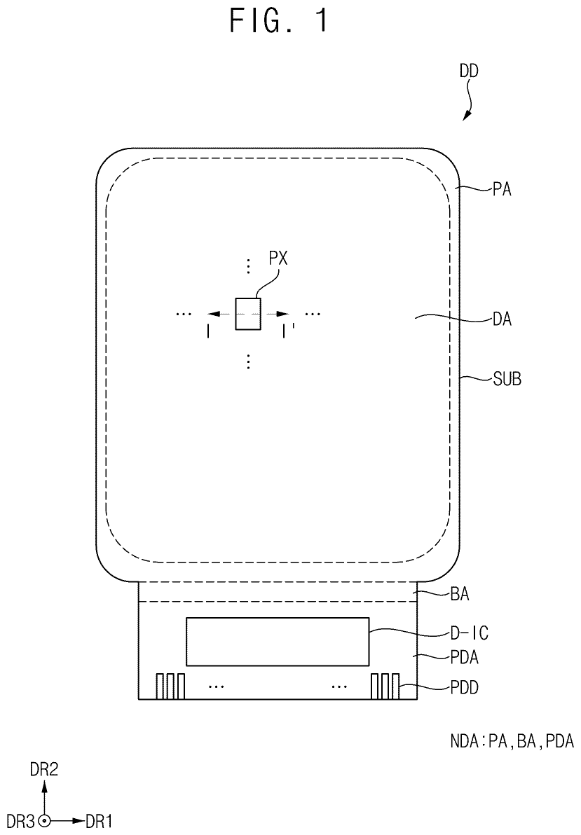

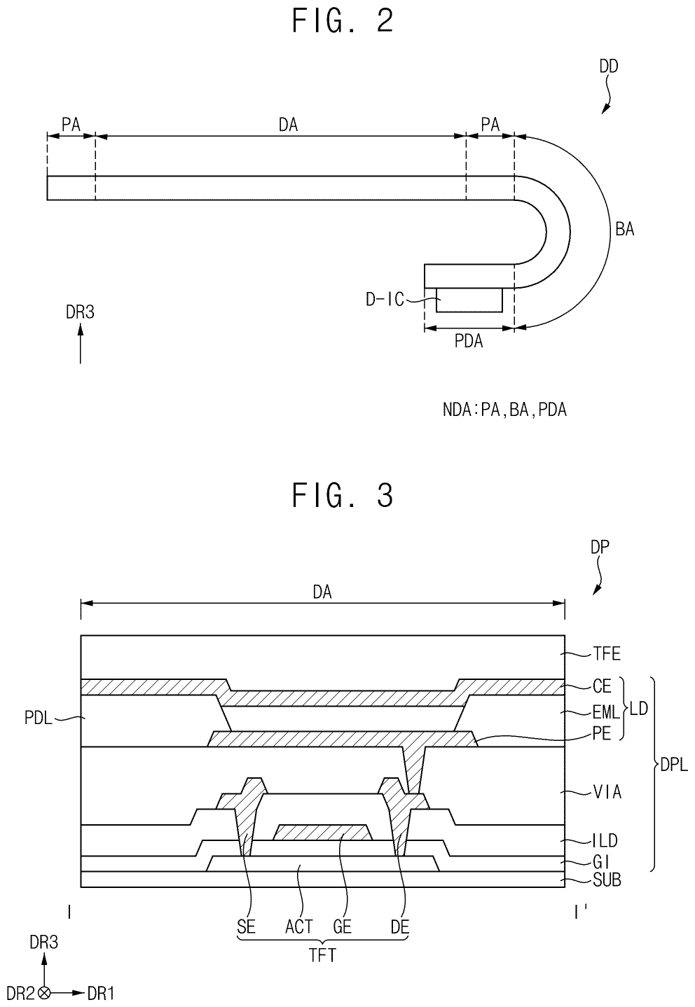

FIG. 1 is a plan view illustrating a display device according to an embodiment of the present disclosure. FIG. 2 is a view illustrating a bent shape of the display device of FIG. 1.

In this specification, a plane may be defined by a first direction DR1 and a second direction DR2 intersecting the first direction DR1. For example, the first direction DR1 and the second direction DR2 may be perpendicular to each other. A direction normal to the plane defined by the first direction DR1 and the second direction DR2, that is, a thickness direction of a display device DD, may be a third direction DR3. In other words, the third direction DR3 may be perpendicular to each of the first direction DR1 and the second direction DR2. As used herein the “a plan view” is a view in the third direction DR3.

Referring to FIGS. 1 and 2, the display device DD according to an embodiment of the present disclosure may include a substrate SUB, a plurality of pixels PX, a driving chip D-IC, and a plurality of pads PDD.

The display device DD may include a display area DA and a non-display area NDA. The display area DA may be defined as an area that displays an image by generating light or adjusting the transmittance of light provided from an external light source. The pixels PX may be disposed in the display area DA on the substrate SUB. Each of the pixels PX may generate light in response to a driving signal. For example, the pixels PX may be disposed in a matrix form along the first direction DR1 and the second direction DR2.

The non-display area NDA may be defined as an area that does not display an image. The non-display area NDA may include a peripheral area PA, a bending area BA, and a pad area PDA.

The peripheral area PA may be positioned around the display area DA. The peripheral area PA may surround at least a portion of the display area DA. For example, the peripheral area PA may entirely surround the display area DA in a plan view.

The bending area BA may extend from one side of the peripheral area PA. As illustrated in FIG. 2, the substrate SUB may be bent downward about a reference axis parallel to the first direction DR1 in the bending area BA. In this case, the pad area PDA may be positioned on a lower surface of the display device DD. The pad area PDA may extend from the bending area BA and may be positioned under the display area DA or the peripheral area PA when the display device DD is bent. When the display device DD is unfolded, the bending area BA may be positioned between the peripheral area PA and the pad area PDA.

The pad area PDA may be spaced apart from the display area DA with the bending area BA interposed between the pad area PDA and the display area DA in a plan view. For example, the pad area PDA may be spaced apart from the display area DA in the second direction DR2. The pads PDD may be disposed in the pad area PDA on the substrate SUB.

The driving chip D-IC may be disposed in the pad area PDA on the substrate SUB. The driving chip D-IC may be connected to the pads PDD through an anisotropic conductive film (“ACF”). Specifically, the driving chip D-IC may include a plurality of bumps, and the plurality of bumps may be connected to the pads PDD through the anisotropic conductive film, respectively. The driving chip D-IC may provide the driving signal to the pixels PX. The driving signal may include various signals to drive the pixels PX, such as a driving voltage, a control signal, a data voltage, etc.

Although not illustrated in FIGS. 1 and 2, a printed circuit board may be disposed in the pad areas PDA on the substrate SUB. The printed circuit board may be connected to the pads PDD through an anisotropic conductive film. For example, the printed circuit board may be a flexible printed circuit board (“FPCB”).

FIG. 3 is a cross-sectional view taken along line I-I′ of FIG. 1.

Referring to FIGS. 1 and 3, the display device DD may include a display panel DP, and the display panel DP may include the substrate SUB, a display element layer DPL, and an encapsulation layer TFE.

The substrate SUB may include a transparent material or an opaque material. The substrate SUB may be formed of a transparent resin substrate. A polyimide substrate may be an example of the transparent resin substrate. In this case, the polyimide substrate may include a first organic layer, a first barrier layer, a second organic layer, etc. In an embodiment, the substrate SUB may include a quartz substrate, a synthetic quartz substrate, a calcium fluoride substrate, a fluorine-doped quartz substrate, a soda-lime glass substrate, a non-alkali glass substrate, etc. These may be used alone or in combination with each other.

The display element layer DPL may be disposed in the display area DA on the substrate SUB. The display element layer DPL may include a transistor TFT, a gate insulating layer GI, an inter-layer insulating layer ILD, a via-insulating layer VIA, a light-emitting element LD, and a pixel defining layer PDL. The transistor TFT may include an active pattern ACT, a gate electrode GE, a source electrode SE, and a drain electrode DE. The light-emitting element LD may include a pixel electrode PE, a light-emitting layer EML, and a common electrode CE.

A buffer layer may be disposed between the substrate SUB and the display element layer DPL. The buffer layer may prevent diffusion of metal atoms or impurities from the substrate SUB to an upper structure (e.g., the transistor TFT, the light-emitting element LD, etc.). In addition, the buffer layer may help to obtain a substantially uniform active pattern ACT by controlling a heat transfer rate during a crystallization process for forming the active pattern ACT. For example, the buffer layer may include an inorganic insulating material. In an embodiment, the buffer layer may be omitted.

The active pattern ACT may be disposed on the substrate SUB. The active pattern ACT may include an oxide semiconductor, a silicon semiconductor, an organic semiconductor, etc. For example, the oxide semiconductor may include indium (In), gallium (Ga), tin (Sn), zirconium (Zr), vanadium (V), hafnium (Hf), cadmium (Cd), germanium (Ge), chromium (Cr), titanium (Ti), zinc (Zn), etc. These may be used alone or in combination with each other. The silicon semiconductor may include amorphous silicon, polycrystalline silicon, etc. The active pattern ACT may include a source area, a drain area, and a channel area positioned between the source area and the drain area.

The gate insulating layer GI may be disposed on the active pattern ACT and the substrate SUB. For example, the gate insulating layer GI may cover the active pattern ACT on the substrate SUB and may be disposed along the profile of the active pattern ACT with a substantially uniform thickness. The gate insulating layer GI may include an inorganic insulating material. Examples of the inorganic insulating material that may be used as the gate insulating layer GI may include silicon oxide (SiOₓ), silicon nitride (SiNₓ), silicon oxynitride (SiOₓN_{y}), etc. These may be used alone or in combination with each other. The gate insulating layer GI may electrically insulate the active pattern ACT from the gate electrode GE.

The gate electrode GE may be disposed on the gate insulating layer GI. The gate electrode GE may overlap the channel area of the active pattern ACT in a plan view. The gate electrode GE may include a metal, an alloy, a metal nitride, a conductive metal oxide, a transparent conductive material, etc. Examples of material that may be used as the gate electrode GE may include silver (Ag), an alloy including silver, molybdenum (Mo), an alloy including molybdenum, aluminum (Al), an alloy including aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (“ITO”), indium zinc oxide (“IZO”), etc. These may be used alone or in combination with each other.

The inter-layer insulating layer ILD may be disposed on the gate electrode GE and the gate insulating layer GI. For example, the inter-layer insulating layer ILD may cover the gate electrode GE on the gate insulating layer GI and may be disposed along the profile of the gate electrode GE with a substantially uniform thickness. The inter-layer insulating layer ILD may include an inorganic insulating material. Examples of the inorganic insulating material that may be used as the inter-layer insulating layer ILD may include silicon oxide (SiOₓ), silicon nitride (SiNₓ), silicon oxynitride (SiOₓN_{y}), etc. These may be used alone or in combination with each other. The inter-layer insulating layer ILD may electrically insulate the gate electrode GE from the source electrode SE. In addition, the inter-layer insulating layer ILD may electrically insulate the gate electrode GE from the drain electrode DE.

The source electrode SE and the drain electrode DE may be disposed on the inter-layer insulating layer ILD. The source electrode SE may be connected to the source area of the active pattern ACT through a contact hole penetrating the gate insulating layer GI and the inter-layer insulating layer ILD. The drain electrode DE may be connected to the drain area of the active pattern ACT through a contact hole penetrating the gate insulating layer GI and the inter-layer insulating layer ILD. Each of the source electrode SE and the drain electrode DE may include a metal, an alloy, a metal nitride, a conductive metal oxide, a transparent conductive material, etc. These may be used alone or in combination with each other.

Accordingly, the transistor TFT including the active pattern ACT, the gate electrode GE, the source electrode SE, and the drain electrode DE may be formed on the substrate SUB.

The via-insulating layer VIA may be disposed on the inter-layer insulating layer ILD. For example, the via-insulating layer VIA may be disposed on the inter-layer insulating layer ILD with a relatively thick thickness to sufficiently cover the source electrode SE and the drain electrode DE. The via-insulating layer VIA may include an organic insulating material. Examples of the organic insulating material that may be used as the via-insulating layer VIA may include a photoresist, a polyacryl-based resin, a polyimide-based resin, a polyamide-based resin, a siloxane-based resin, an acryl-based resin, an epoxy-based resin, etc. These may be used alone or in combination with each other.

The pixel electrode PE may be disposed on the via-insulating layer VIA. The pixel electrode PE may be connected to the drain electrode DE through a contact hole penetrating the via-insulating layer VIA. Accordingly, the pixel electrode PE may be electrically connected to the transistor TFT. For example, the pixel electrode PE may be a semi-transmissive electrode, a transmissive electrode, or a reflective electrode. The pixel electrode PE may include a metal, an alloy, a metal nitride, a conductive metal oxide, a transparent conductive material, etc. These may be used alone or in combination with each other. For example, the pixel electrode PE may serve as an anode electrode.

The pixel defining layer PDL may be disposed on the via-insulating layer VIA and the pixel electrode PE. The pixel defining layer PDL may cover edges of the pixel electrode PE and may expose an upper surface of the pixel electrode PE. The pixel defining layer PDL may include an organic insulating material. Examples of the organic insulating material that may be used as the pixel defining layer PDL may include a photoresist, a polyacryl-based resin, a polyimide-based resin, a polyamide-based resin, a siloxane-based resin, an acryl-based resin, an epoxy-based resin, etc. These may be used alone or in combination with each other.

The light-emitting layer EML may be disposed on the pixel electrode PE. Specifically, the light-emitting layer EML may be disposed on the upper surface of the pixel electrode PE not covered by the pixel defining layer PDL. The light-emitting layer EML may emit light having a specific color (e.g., red, green and blue). In an embodiment, the light-emitting layer EML may include one or both of an organic light-emitting material and a quantum dot. For example, the light-emitting layer EML may include an organic material including a fluorescent or phosphorescent material that emits red, green, blue, or white light. The quantum dot may be a particle having a crystal structure of several to tens of nanometers in size, and may include hundreds to thousands of atoms. The quantum dot may include a fluorescent material or a phosphorescent material, and may produce monochromatic red, green, and blue light.

For example, the light-emitting layer EML may have a single-layer structure including one light-emitting layer. However, the present disclosure is not limited thereto, and the light-emitting layer EML may have a tandem structure in which a plurality of light-emitting layers are stacked.

The common electrode CE may be disposed on the pixel defining layer PDL and the light-emitting layer EML. The common electrode CE may cover the pixel defining layer PDL and the light-emitting layer EML and may be disposed along the profiles of the pixel defining layer PDL and the light-emitting layer EML with a substantially uniform thickness. For example, the common electrode CE may include a metal, an alloy, a metal nitride, a conductive metal oxide, a transparent conductive material, etc. These may be used alone or in combination with each other. For example, the common electrode CE may serve as a cathode electrode.

Accordingly, the light-emitting element LD including the pixel electrode PE, the light-emitting layer EML, and the common electrode CE may be formed on the via-insulating layer VIA.

The encapsulation layer TFE may be disposed on the common electrode CE. The encapsulation layer TFE may prevent impurities, moisture, etc. from penetrating into the light-emitting element LD from the outside. The encapsulation layer TFE may include at least one inorganic encapsulation layer and at least one organic encapsulation layer. For example, the inorganic encapsulation layer may include silicon oxide (SiOₓ), silicon nitride (SiNₓ), silicon oxynitride (SiOₓN_{y}), etc. These may be used alone or in combination with each other. For example, the organic encapsulation layer may include a cured polymer such as polyacrylate.

Although the display device DD including the organic light emitting diode (“OLED”) display device is described, the configuration of the present disclosure is not limited thereto. In other embodiments, the display device DD may include a liquid crystal display (“LCD”) device, a field emission display (“FED”) device, a plasma display panel (“PDP”) device, an electrophoretic image display (“EPD”) device, an inorganic light emitting diode (“ILED”) display device, or a quantum dot display device.

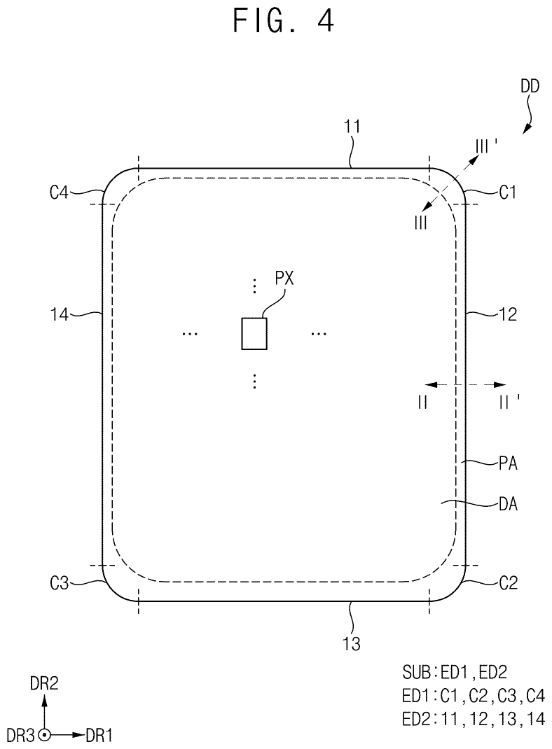

FIG. 4 is a plan view illustrating the display device of FIG. 1. For convenience of description, the bending area BA and the pad area PDA of FIG. 1 are omitted in FIG. 4.

Referring to FIG. 4, the display device DD may include the substrate SUB and the pixels PX, and the substrate SUB may have a first edge ED1 and a second edge ED2. The first edge ED1 may include first to fourth curved portions C1, C2, C3, C4, and the second edge ED2 may include first to fourth sides 11, 12, 13, 14.

The substrate SUB may have a planar shape of a square with rounded corners. That is, the first edge ED1 of the substrate SUB may include the first to fourth curved portions C1, C2, C3, C4 having a predetermined curvature, and the second edge ED2 of the substrate SUB may include the first to fourth sides 11, 12, 13, 14 extending in a straight line.

The first side 11 and the third side 13 may face each other and may extend parallel to each other along the first direction DR1. The second side 12 and the fourth side 14 may face each other and may extend parallel to each other along the second direction DR2. In an embodiment, a length of the first side 11 may be shorter than a length of the second side 12. However, the present disclosure is not limited thereto, and the length of the first side 11 may be longer than the length of the second side 12.

The first curved portion C1 may be positioned between the first side 11 and the second side 12. The first curved portion C1 may have a predetermined curvature in a plan view. The first curved portion C1 may connect the first side 11 and the second side 12. That is, the first curved portion C1 may contact the first side 11 and the second side 12.

The second curved portion C2 may be positioned between the second side 12 and the third side 13. The second curved portion C2 may have a predetermined curvature in a plan view. The second curved portion C2 may connect the second side 12 and the third side 13. That is, the second curved portion C2 may contact the second side 12 and the third side 13.

The third curved portion C3 may be positioned between the third side 13 and the fourth side 14. The third curved portion C3 may have a predetermined curvature in a plan view. The third curved portion C3 may connect the third side 13 and the fourth side 14. That is, the third curved portion C3 may contact the third side 13 and the fourth side 14.

The fourth curved portion C4 may be positioned between the first side 11 and the fourth side 14. The fourth curved portion C4 may have a predetermined curvature in a plan view. The fourth curved portion C4 may connect the first side 11 and the fourth side 14. That is, the fourth curved portion C4 may contact the first side 11 and the fourth side 14.

The first curved portion C1, the second curved portion C2, the third curved portion C3, and the fourth curved portion C4 may have shapes that are substantially identical or symmetrical to each other. Therefore, hereinafter, the description will focus on the first curved portion C1. The description of the first curved portion C1 may be equally applicable to the second to fourth curved portions C2, C3, C4.

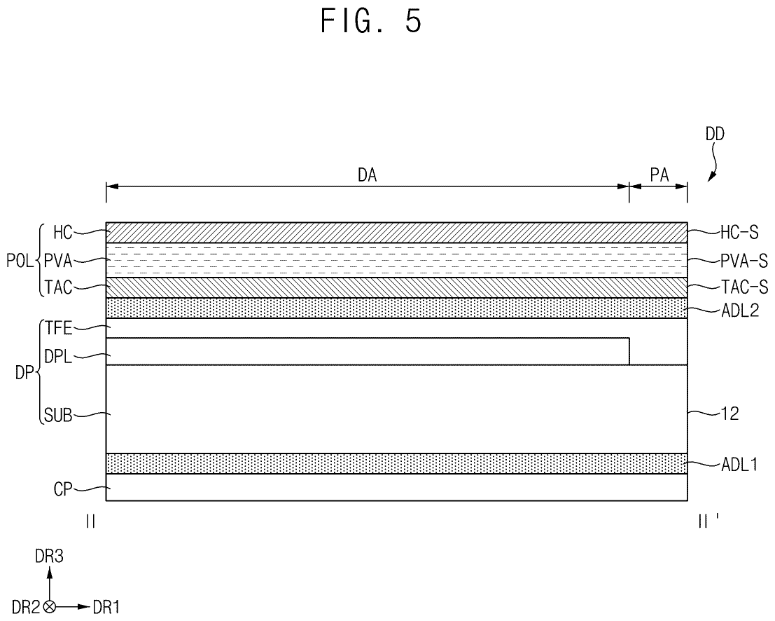

FIG. 5 is a cross-sectional view taken along line II-II′ of FIG. 4. For example, FIG. 5 illustrates a cross-section structure of the display device DD in an area adjacent to or overlapping the second side 12 of FIG. 4 in a plan view.

Referring to FIGS. 4 and 5, the display device DD may include the display panel DP, a first adhesive layer ADL1, a cover panel CP, a second adhesive layer ADL2, and a polarization layer POL. The display panel DP may include the substrate SUB, the display element layer DPL, and the encapsulation layer TFE. As described above, the display element layer DPL may include the transistor TFT, the gate insulating layer GI, the inter-layer insulating layer ILD, the via-insulating layer VIA, the light-emitting element LD, and the pixel defining layer PDL that are illustrated in FIG. 3. The polarization layer POL may include a first functional layer TAC, a polarization film PVA, and a second functional layer HC.

The first adhesive layer ADL1 may be disposed between the display panel DP and the cover panel CP. The first adhesive layer ADL1 may overlap the display area DA and the peripheral area PA. The first adhesive layer ADL1 may attach the display panel DP and the cover panel CP. For example, the first adhesive layer ADL1 may include a pressure sensitive adhesive (“PSA”) film, an optically clear adhesive (“OCA”) film, or an optically clear resin (“OCR”). In an embodiment, the first adhesive layer ADL1 may include a pressure sensitive adhesive film, but the present disclosure is not limited thereto.

The cover panel CP may be disposed under the display panel DP. The cover panel CP may overlap the display area DA and the peripheral area PA. The cover panel CP may be attached to a lower surface of the display panel DP through the first adhesive layer ADL1. Specifically, the cover panel CP may be attached to a lower surface of the substrate SUB through the first adhesive layer ADL1. The cover panel CP may protect the display panel DP from external impact. The cover panel CP may include an organic material. Examples of the organic material that may be used as the cover panel CP may include polyethylene terephthalate (“PET”), polyimide (“PI”), polyethylene naphthalate (“PEN”), etc. These may be used alone or in combination with each other. In an embodiment, the cover panel CP may further include a metal for dissipating heat. For example, the cover panel CP may further include aluminum (Al), copper (Cu), etc.

Although not illustrated, in an embodiment, a touch sensing panel may be disposed on the display panel DP. The touch sensing panel may overlap the display area DA and the peripheral area PA. The touch sensing panel may be disposed directly on the display panel DP. In other words, the touch sensing panel may be formed directly on the display panel DP without an adhesive member.

For example, the touch sensing panel may include a plurality of touch electrode arrays for sensing a user's touch in a capacitive manner, a touch pad portion, and a plurality of touch lines that electrically connect the touch electrode arrays and the touch pad portion. However, the present disclosure is not limited thereto. In an embodiment, the touch sensing panel may be omitted.

The second adhesive layer ADL2 may be disposed between the display panel DP and the polarization layer POL. The second adhesive layer ADL2 may overlap the display area DA and the peripheral area PA. The second adhesive layer ADL2 may attach the display panel DP and the polarization layer POL. For example, the second adhesive layer ADL2 may include a pressure sensitive adhesive (“PSA”) film, an optically clear adhesive (“OCA”) film, or an optically clear resin (“OCR”). In an embodiment, the second adhesive layer ADL2 may include a pressure sensitive adhesive film, but the present disclosure is not limited thereto.

The polarization layer POL may be disposed on the display panel DP. The polarization layer POL may overlap the display area DA and the peripheral area PA. The polarization layer POL may be attached to an upper surface of the display panel DP through the second adhesive layer ADL2. Specifically, the polarization layer POL may be attached to an upper surface of the encapsulation layer TFE through the second adhesive layer ADL2. The polarization layer POL may reduce the external light reflection of the display device DD. As the external light reflection is reduced, the visibility of the display device DD may be improved. The polarization layer POL may include the first functional layer TAC, the polarization film PVA disposed on the first functional layer TAC, and the second functional layer HC disposed on the polarization film PVA.

The first functional layer TAC may be disposed between the display panel DP and the polarization film PVA. Specifically, the first functional layer TAC may be attached to the upper surface of the encapsulation layer TFE through the second adhesive layer ADL2. The first functional layer TAC may protect the polarization film PVA. For example, the first functional layer TAC may include tri-acetyl cellulose.

The polarization film PVA may be disposed on the first functional layer TAC. The polarization film PVA may include a polarizer of a stretched film type. For example, the polarization film PVA may include a stretched polymer such as stretched polyvinyl alcohol. For example, the polarization film PVA may be formed by stretching an iodine-adsorbed polyvinyl alcohol film.

The second functional layer HC may be disposed on the polarization film PVA. The second functional layer HC may protect the polarization film PVA. For example, the second functional layer HC may include tri-acetyl cellulose. In an embodiment, the second functional layer HC may be formed by coating the tri-acetyl cellulose to have desired surface properties. For example, the second functional layer HC may be formed by coating treatment with a material that provides surface properties such as anti-glare properties, anti-reflection properties, scratch resistance, fingerprint resistance, etc.

In an embodiment, in an area adjacent to or overlapping the second side 12 in a plan view, a side surface TAC-S of the first functional layer TAC, a side surface PVA-S of the polarization film PVA, and a side surface HC-S of the second functional layer HC may be substantially aligned along a thickness direction of the substrate SUB (e.g., the third direction DR3). Similarly, in areas adjacent to or overlapping the first side 11, the third side 13, and the fourth side 14 in a plan view, the side surface TAC-S of the first functional layer TAC, the side surface PVA-S of the polarization film PVA, and the side surface HC-S of the second functional layer HC may be substantially aligned along the thickness direction of the substrate SUB. In other words, in areas adjacent to or overlapping the second edge ED2 of the substrate SUB extending in a straight line in a plan view, the side surface TAC-S of the first functional layer TAC, the side surface PVA-S of the polarization film PVA, and the side surface HC-S of the second functional layer HC may be substantially aligned along the thickness direction of the substrate SUB. In other words, the side surface TAC-S of the first functional layer TAC, the side surface PVA-S of the polarization film PVA, and the side surface HC-S of the second functional layer HC may be exposed. In this case, the first functional layer TAC may be spaced apart from the second functional layer HC with the polarization film PVA interposed therebetween.

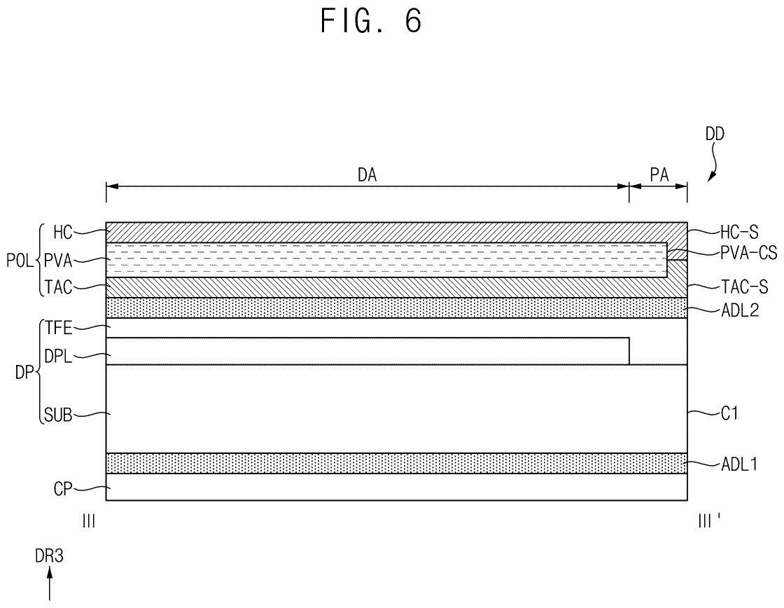

FIG. 6 is a cross-sectional view taken along line III-III′ of FIG. 4. For example, FIG. 6 illustrates a cross-section structure of the display device DD in an area adjacent to or overlapping the first curved portion C1 of FIG. 4 in a plan view.

Referring to FIGS. 4 and 6, the display device DD may include the display panel DP, the first adhesive layer ADL1, the cover panel CP, the second adhesive layer ADL2, and the polarization layer POL. The display panel DP may include the substrate SUB, the display element layer DPL, and the encapsulation layer TFE. The polarization layer POL may include the first functional layer TAC, the polarization film PVA, and the second functional layer HC. Hereinafter, redundant description of a cross-section structure of the display device DD in the area adjacent to or overlapping the second side 12 in a plan view described above with reference to FIG. 5 may be omitted or may be summarized.

The polarization film PVA may be disposed on the first functional layer TAC. Specifically, the polarization film PVA may be disposed between the first functional layer TAC and the second functional layer HC. The polarization film PVA may include a polarizer of a stretched film type. For example, the polarization film PVA may include a stretched polymer such as stretched polyvinyl alcohol.

In exemplary embodiments, in an area adjacent to or overlapping the first curved portion C1 in a plan view, the polarization film PVA may have a side surface PVA-CS that is recessed from the side surface TAC-S of the first functional layer TAC and the side surface HC-S of the second functional layer HC toward a central portion of the substrate SUB. In other words, in the area adjacent to or overlapping the first curved portion C1 in a plan view, the polarization film PVA may have the side surface PVA-CS recessed toward a central portion of the polarization layer POL. Similarly, in areas adjacent to or overlapping the second curved portion C2, the third curved portion C3, and the fourth curved portion C4 in a plan view, the polarization film PVA may have the side surface PVA-CS recessed toward the central portion of the substrate SUB. In other words, in an area adjacent to or overlapping the first edges ED1 of the substrate SUB extending in a curve with a predetermined curvature in a plan view, the polarization film PVA may have the side surface PVA-CS recessed toward the central portion of the substrate SUB.

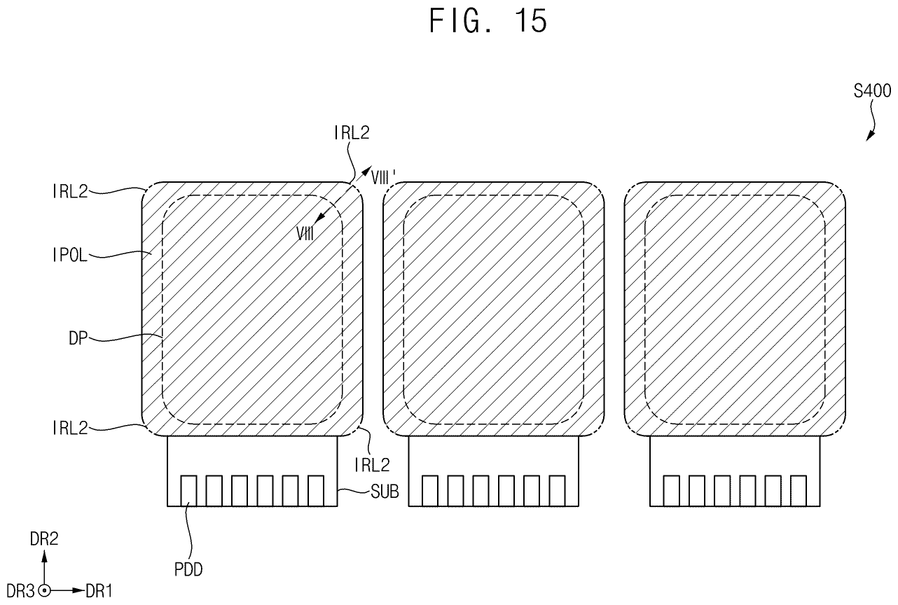

In exemplary embodiments, in the area adjacent to or overlapping the first curved portion C1 in a plan view, the first functional layer TAC and the second functional layer HC may cover the side surface PVA-CS of the polarization film PVA. In other words, the recessed side surface PVA-CS of the polarization film PVA may be sealed by the first functional layer TAC and the second functional layer HC. In this case, in the area adjacent to or overlapping the first curved portion C1 in a plan view, the first functional layer TAC and the second functional layer HC may contact each other. Similarly, in the areas adjacent to or overlapping the second curved portion C2, the third curved portion C3, and the fourth curved portion C4 in a plan view, the first functional layer TAC and the second functional layer HC may cover the recessed side surface PVA-CS of the polarization film PVA. In other words, in the area adjacent to or overlapping the first edge ED1 of the substrate SUB extending in a curve with a predetermined curvature in a plan view, the first functional layer TAC and the second functional layer HC may cover the recessed side surface PVA-CS of the polarization film PVA. Accordingly, the first functional layer TAC and the second functional layer HC may prevent moisture from penetrating into the recessed side surface PVA-CS of the polarization film PVA. As a result, defects of the polarization layer POL due to moisture may be suppressed, and the reliability of the polarization layer POL may be improved. A detailed description thereof will be described below with reference to FIGS. 15, 16, 17, and 18.

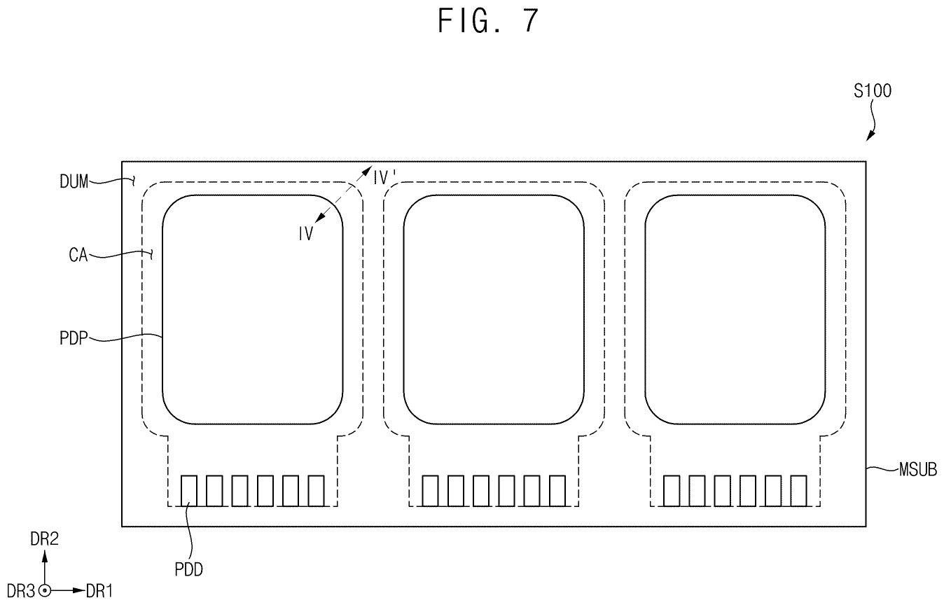

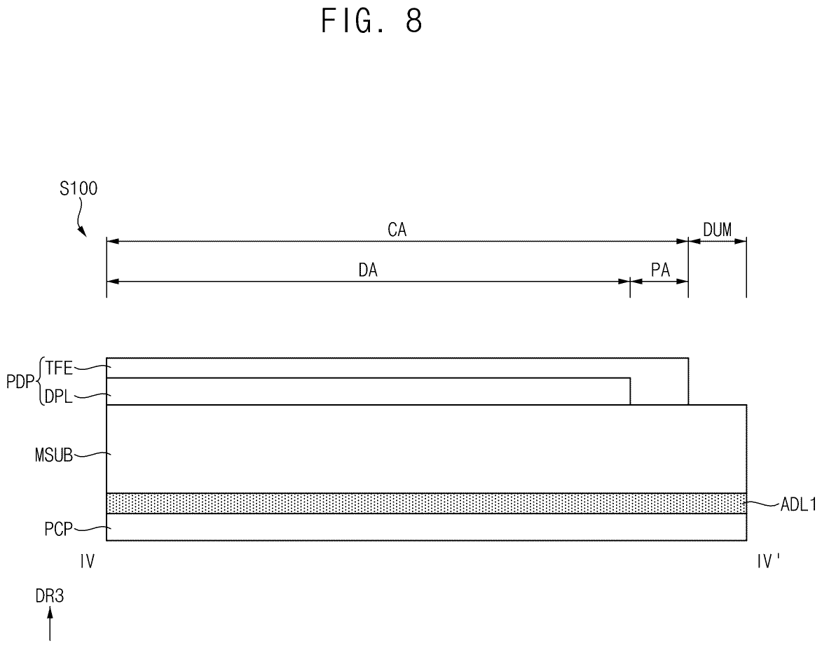

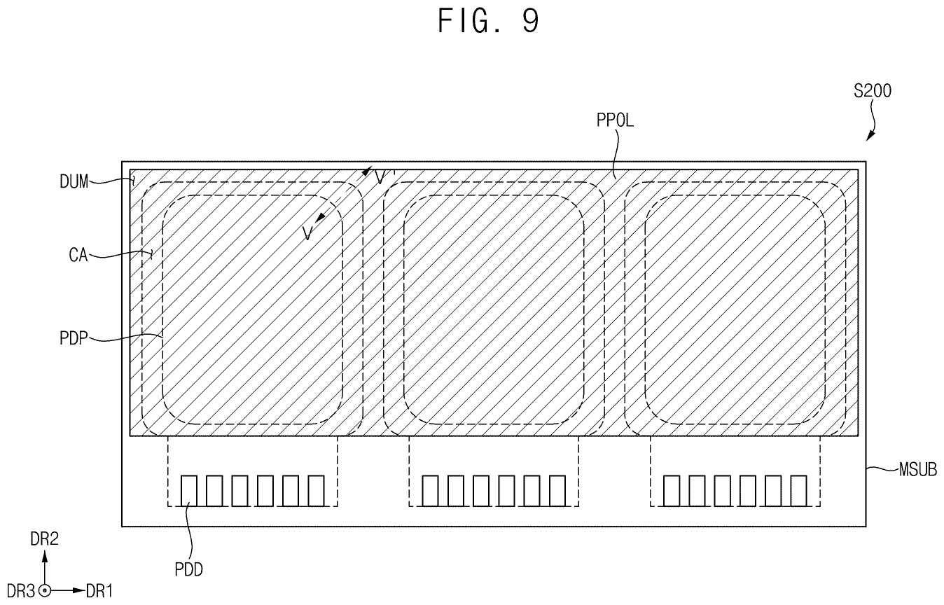

FIGS. 7, 8, 9, 10, 11, 12, 13, 14, 15, 16, 17, and 18 are views illustrating a method of manufacturing a display device according to an embodiment of the present disclosure. For example, FIGS. 7, 9, 11, 13, 15, and 17 are plan views illustrating the method of manufacturing the display device according to an embodiment of the present disclosure. FIGS. 8, 10, 12, 14, 16, and 18 are cross-sectional views illustrating the method of manufacturing the display device according to an embodiment of the present disclosure.

Referring to FIGS. 7 and 8, a preliminary display panel PDP and pads PDD overlapping a cell area CA may be formed on a first surface of a mother substrate MSUB (S100). The mother substrate MSUB may include a transparent material or an opaque material.

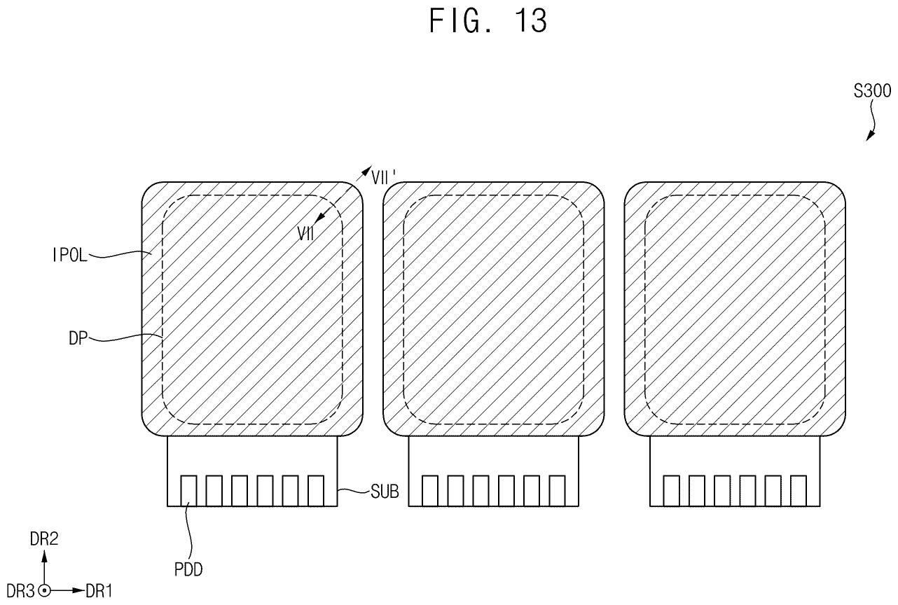

For example, the mother substrate MSUB may be formed of a transparent resin substrate. A polyimide substrate may be an example of the transparent resin substrate. In an embodiment, the mother substrate MSUB may include a quartz substrate, a synthetic quartz substrate, a calcium fluoride substrate, a fluorine-doped quartz substrate, a soda-lime glass substrate, a non-alkali glass substrate, etc. These may be used alone or in combination with each other. The mother substrate MSUB may include a plurality of substrates (SUB, refer to FIG. 13). The mother substrate MSUB may be separated to form the plurality of substrates in a subsequent process.

The mother substrate MSUB may include the cell area CA and a dummy area DUM. The cell area CA may include the display area DA and the non-display area (NDA, refer to FIG. 1). The dummy area DUM may be positioned around the cell area CA. In an embodiment, the dummy area DUM may surround the cell area CA. For example, the dummy area DUM may entirely surround the cell area CA. The dummy area DUM may be defined as an area that is removed in a subsequent process.

The light-emitting elements (LD, refer to FIG. 3) and the pads PDD may be formed on the first surface of the mother substrate MSUB to overlap the cell area CA. Specifically, the preliminary display panel PDP and the pads PDD may be formed on the first surface of the mother substrate MSUB in the cell area CA. The preliminary display panel PDP may overlap the display area DA and the pads PDD may overlap the non-display area (specifically, the pad area PDA of FIG. 1).

The preliminary display panel PDP may include the display element layer DPL and the encapsulation layer TFE disposed on the display element layer DPL. As described above, the display element layer DPL may include the transistor TFT, the gate insulating layer GI, the inter-layer insulating layer ILD, the via-insulating layer VIA, the light-emitting element LD, and the pixel defining layer PDL that are illustrated in FIG. 3. The display element layer DPL may overlap the display area DA, and the encapsulation layer TFE may overlap the display area DA and the peripheral area PA.

A preliminary cover panel PCP may be formed on a second surface opposite to the first surface of the mother substrate MSUB. The preliminary cover panel PCP may be attached to the second surface of the mother substrate MSUB through the first adhesive layer ADL1. The preliminary cover panel PCP may overlap the cell area CA and the dummy area DUM.

As illustrated in FIG. 7, three preliminary display panels PDP may be formed on the mother substrate MSUB, but the present disclosure is not limited thereto. The number of the preliminary display panels PDP formed on the mother substrate MSUB may vary depending on embodiments.

As illustrated in FIG. 7, the mother substrate MSUB may have a rectangular planar shape. That is, the mother substrate MSUB may have a rectangular planar shape with a long side extending in the first direction DR1 and a short side extending in the second direction DR2. However, the planar shape of the mother substrate MSUB is not limited thereto.

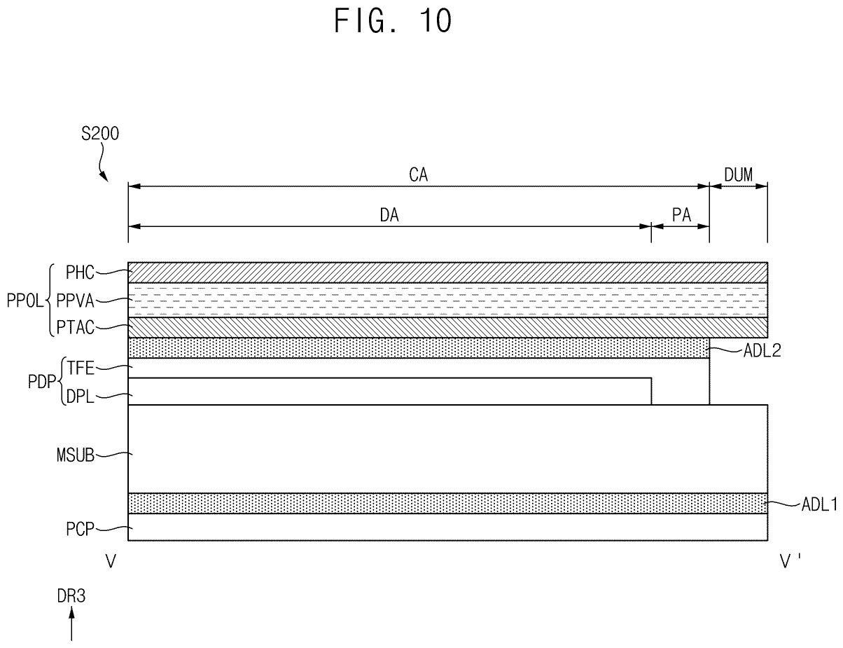

Referring to FIGS. 9 and 10, a preliminary polarization layer PPOL may be formed on the light-emitting element (S200). Specifically, the preliminary polarization layer PPOL overlapping the preliminary display panel PDP may be formed on the first surface of the mother substrate MSUB.

The preliminary polarization layer PPOL may be formed on the preliminary display panel PDP. Specifically, the preliminary polarization layer PPOL may be attached to an upper surface of the encapsulation layer TFE through the second adhesive layer ADL2. The preliminary polarization layer PPOL may overlap a portion of the cell area CA and the dummy area DUM. Specifically, the preliminary polarization layer PPOL may overlap the display area DA and the peripheral area PA, and may not overlap the bending area (BA, refer to FIG. 1) and the pad area (PDA, refer to FIG. 1). That is, the preliminary polarization layer PPOL may be spaced apart from the pads PDD in a plan view. A thickness (or, a length in the third direction (DR3)) of the preliminary polarization layer PPOL may be about 90 micrometers to about 100 micrometers. However, the present disclosure is not limited thereto. The preliminary polarization layer PPOL may include a first preliminary functional layer PTAC, a preliminary polarization film PPVA, and a second preliminary functional layer PHC sequentially stacked.

The first preliminary functional layer PTAC may be formed on the encapsulation layer TFE. Specifically, the first preliminary functional layer PTAC may be attached to the upper surface of the encapsulation layer TFE through the second adhesive layer ADL2. For example, the first preliminary functional layer PTAC may include tri-acetyl cellulose.

The preliminary polarization film PPVA may be formed on the first preliminary functional layer PTAC. The preliminary polarization film PPVA may entirely overlap the first preliminary functional layer PTAC. For example, the preliminary polarization film PPVA may be formed by stretching a polyvinyl alcohol film to which iodine is adsorbed.

The second preliminary functional layer PHC may be disposed on the preliminary polarization film PPVA. The second preliminary functional layer PHC may entirely overlap the preliminary polarization film PPVA. In an embodiment, the second preliminary functional layer PHC may be formed by coating the tri-acetyl cellulose to have desired surface properties. For example, the second preliminary functional layer PHC may be formed by coating treatment with a material that provides surface properties such as anti-glare properties, anti-reflection properties, scratch resistance, fingerprint resistance, etc.

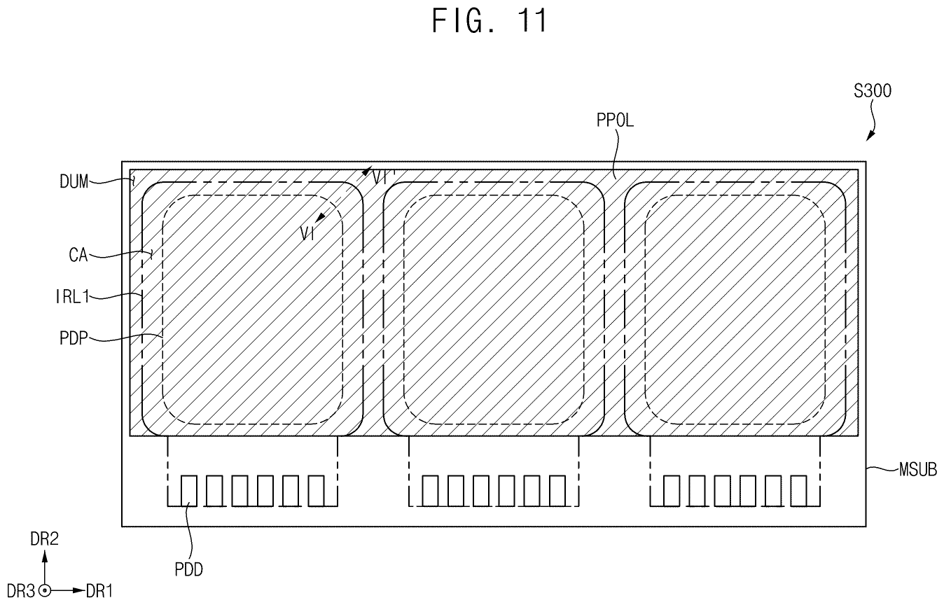

Referring to FIGS. 11, 12, 13, and 14, a first laser LAS1 may be irradiated along edges of the cell area CA (S300). Accordingly, the mother substrate MSUB, the preliminary polarization layer PPOL, and the preliminary cover panel PCP may be cut.

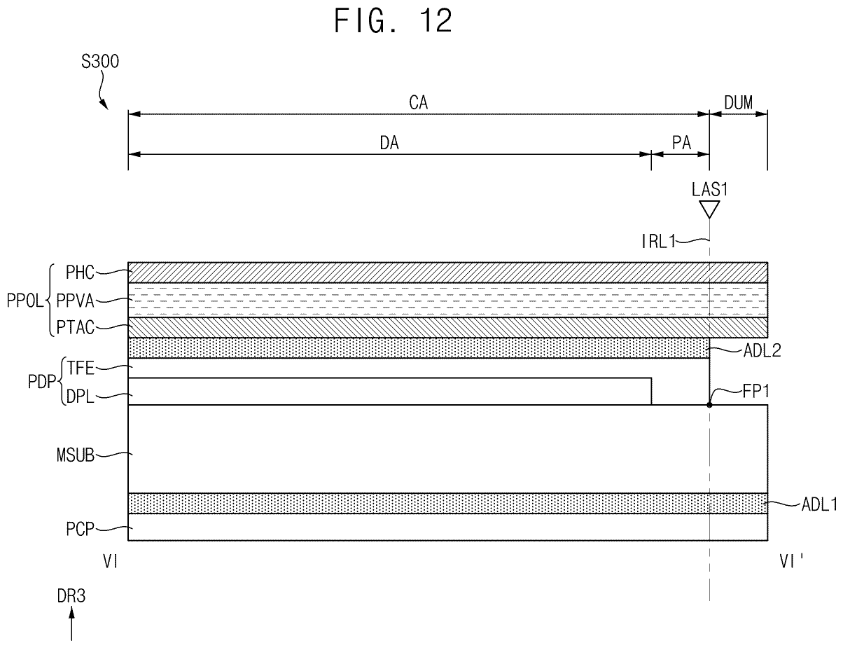

As illustrated in FIGS. 11 and 12, the first laser LAS1 may be irradiated toward the mother substrate MSUB along a first irradiation line IRL1. The first irradiation line IRL1 may be substantially equal to the edge of the cell area CA of the mother substrate MSUB.

In an embodiment, as illustrated in FIG. 12, the first laser LAS1 may be irradiated from an upper portion of the preliminary polarization layer PPOL toward the mother substrate MSUB. However, the present disclosure is not limited thereto, and the first laser LAS1 may also be irradiated from a lower portion of the preliminary cover panel PCP toward the mother substrate MSUB. For example, the first laser LAS1 may be implemented as a gas laser such as a helium-neon (He—Ne) laser in the infrared wavelength range, a UV laser, a carbon dioxide (CO₂) laser, or the like. However, the present disclosure is not limited thereto.

To irradiate the first laser LAS1 to cut the preliminary polarization layer PPOL, the mother substrate MSUB, and the preliminary cover panel PCP, a depth of focus of the first laser LAS1 may be adjusted. To adjust the depth of focus of the first laser LAS1, a distance between the first laser LAS1 and the mother substrate MSUB may be adjusted. For example, a laser scanner irradiating the first laser LAS1 may be driven by a laser driver, and the laser driver may move the laser scanner in the third direction DR3 or in the opposite direction of the third direction DR3. For another example, the mother substrate MSUB may be loaded on a stage, and the stage may be driven by a stage driver, wherein the stage driver may move the mother substrate MSUB and the stage in the third direction DR3 or the opposite direction of the third direction DR3.

In an embodiment, a first focus FP1 of the first laser LAS1 may be formed at the mother substrate MSUB. For example, as illustrated in FIG. 12, the first focus FP1 of the first laser LAS1 may be formed at the first surface (or, an upper surface) of the mother substrate MSUB. However, the present disclosure is not limited thereto, and the first focus FP1 of the first laser LAS1 may be formed at the second surface (or, a lower surface) of the mother substrate MSUB or within a space between the upper surface and the lower surface of the mother substrate MSUB.

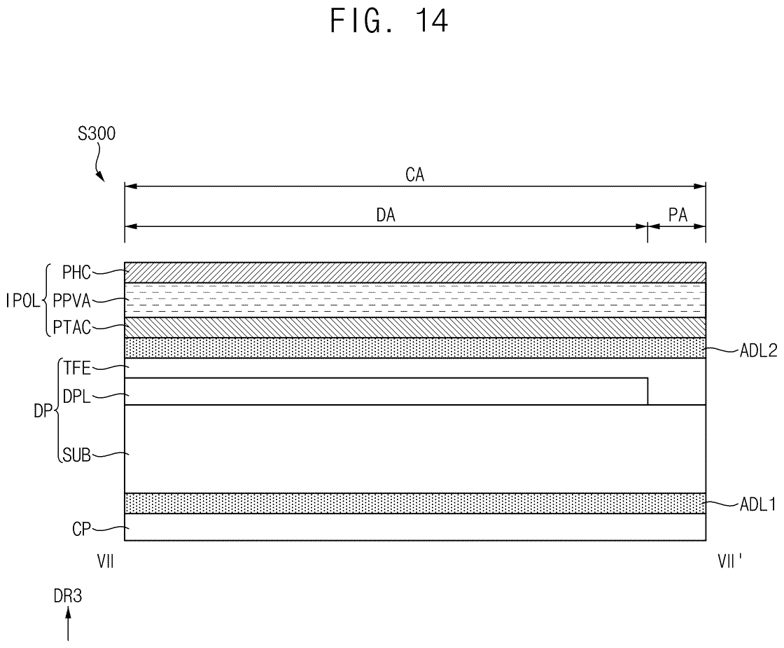

Accordingly, as illustrated in FIGS. 13 and 14, the mother substrate MSUB, the preliminary polarization layer PPOL, and the preliminary cover panel PCP may be cut simultaneously by the first laser LAS1.

The mother substrate MSUB may be cut along the edge of the cell area CA to remove a portion of the mother substrate MSUB in the dummy area DUM. Accordingly, the plurality of substrates SUB may be formed. In addition, a portion of the preliminary cover panel PCP in the dummy area DUM may be removed to form the cover panel CP overlapping the cell area CA.

In addition, a portion of the preliminary polarization layer PPOL in the dummy area DUM may be removed to form an intermediate polarization layer IPOL. Specifically, a portion of the first preliminary functional layer PTAC, a portion of the preliminary polarization film PPVA, and a portion of the second preliminary functional layer PHC in the dummy area DUM may be removed to form the intermediate polarization layer IPOL. The intermediate polarization layer IPOL may overlap the cell area CA. That is, the intermediate polarization layer IPOL may overlap the display area DA and the peripheral area PA. The first preliminary functional layer PTAC of the intermediate polarization layer IPOL may be spaced apart from the second preliminary functional layer PHC with the preliminary polarization film PVA interposed therebetween.

Referring to FIGS. 15, 16, 17, and 18, a second laser LAS2 may be irradiated along the first edge (ED1, refer to FIG. 4) of the substrate SUB that extends in a curve with a predetermined curvature (S400). That is, the second laser LAS2 may be irradiated along the first edge of the substrate SUB that extends in a curve and may not be irradiated at the second edge (ED2, refer to FIG. 4) of the substrate SUB that extends in a straight line.

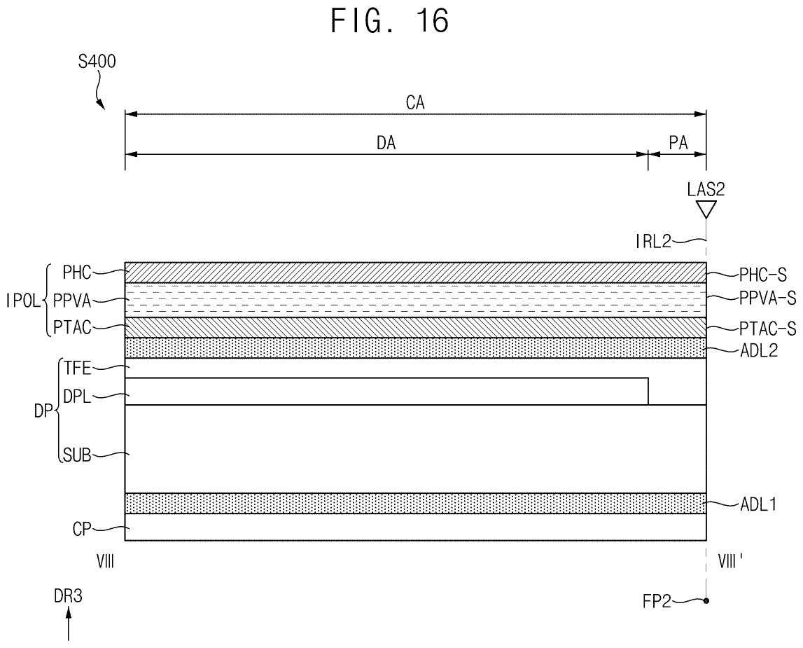

As illustrated in FIGS. 15 and 16, the second laser LAS2 may be irradiated toward the substrate SUB along a second irradiation line IRL2. The second irradiation line IRL2 may correspond to the first edge ED1 of FIG. 4. In other words, the second irradiation line IRL2 may correspond to the first to fourth curved portions C1, C2, C3, C4 of FIG. 4. In an embodiment, as illustrated in FIG. 16, the second laser LAS2 may be irradiated from an upper portion of the intermediate polarization layer IPOL toward the substrate SUB. For example, the second laser LAS2 may be implemented as a gas laser such as a helium-neon (He—Ne) laser in the infrared wavelength range, a UV laser, a carbon dioxide (CO₂) laser, or the like. However, the present disclosure is not limited thereto.

The second laser LAS2 may be irradiated to provide thermal energy to the intermediate polarization layer IPOL. That is, the second laser LAS2 may provide thermal energy to the intermediate polarization layer IPOL, and may not cut a layer to which the second laser LAS2 is irradiated. To provide thermal energy to the intermediate polarization layer IPOL without cutting the layer, a depth of focus of the second laser LAS2 may be adjusted. In order to adjust the depth of focus of the second laser LAS2, a distance between the second laser LAS2 and the substrate SUB may be adjusted.

In an embodiment, a second focus FP2 of the second laser LAS2 may be formed at a different position from the first focus FP1 of the first laser LAS1 of FIG. 12. For example, as illustrated in FIG. 16, the second focus FP2 of the second laser LAS2 may be formed under the first focus FP1 of the first laser LAS1 of FIG. 12. In this case, the first focus FP1 may be formed at the mother substrate (MSUB, refer to FIG. 12), and the second focus FP2 may be formed under the cover panel CP. Accordingly, the second laser LAS2 may provide thermal energy to the intermediate polarization layer IPOL, the substrate SUB, and the cover panel CP without cutting the intermediate polarization layer IPOL. However, the present disclosure is not limited thereto, and the second focus FP2 of the second laser LAS2 may be formed above the first focus FP1 of the first laser LAS1.

In an embodiment, a distance between the first focus FP1 and the second focus FP2 may be about 500 micrometers to about 3 millimeters or about 500 micrometers to about 2 millimeters. For example, the second focus FP2 may be formed about 500 micrometers to about 3 millimeters or about 500 micrometers to about 2 millimeters under the first focus FP1. For another example, the second focus FP2 may be formed about 500 micrometers to about 3 millimeters or about 500 micrometers to about 2 millimeters above the first focus FP1. When the distance between the first focus FP1 and the second focus FP2 is less than about 500 micrometers, the intermediate polarization layer IPOL, the substrate SUB, or the cover panel CP may be cut by the second laser LAS2. When the distance between the first focus FP1 and the second focus FP2 is greater than about 3 millimeters, sufficient thermal energy may not be provided to deform the first preliminary functional layer PTAC, the preliminary polarization film PPVA, and the second preliminary functional layer PHC. In an embodiment, the second focus FP2 of the second laser LAS2 may be formed under the substrate SUB. For example, the second focus FP2 may be formed under the cover panel CP.

In an embodiment, the second focus FP2 of the second laser LAS2 may be formed about 500 micrometers to about 3 millimeters or about 500 micrometers to about 2 millimeters under a lower surface of the first preliminary functional layer PTAC. That is, a distance between the second focus FP2 of the second laser LAS2 and the lower surface of the first preliminary functional layer PTAC may be about 500 micrometers to about 3 millimeters or about 500 micrometers to about 2 millimeters. For example, a thickness of the intermediate polarization layer IPOL may be about 90 micrometers to about 100 micrometers. In addition, a total thickness of the cover panel CP, the substrate SUB, the display element layer DPL, the encapsulation layer TFE, the first adhesion layer ADL1, the second adhesion layer ADL2, and the intermediate polarization layer IPOL may be from about 300 micrometers to about 400 micrometers. In this case, the second focus FP2 may be formed under the cover panel CP.

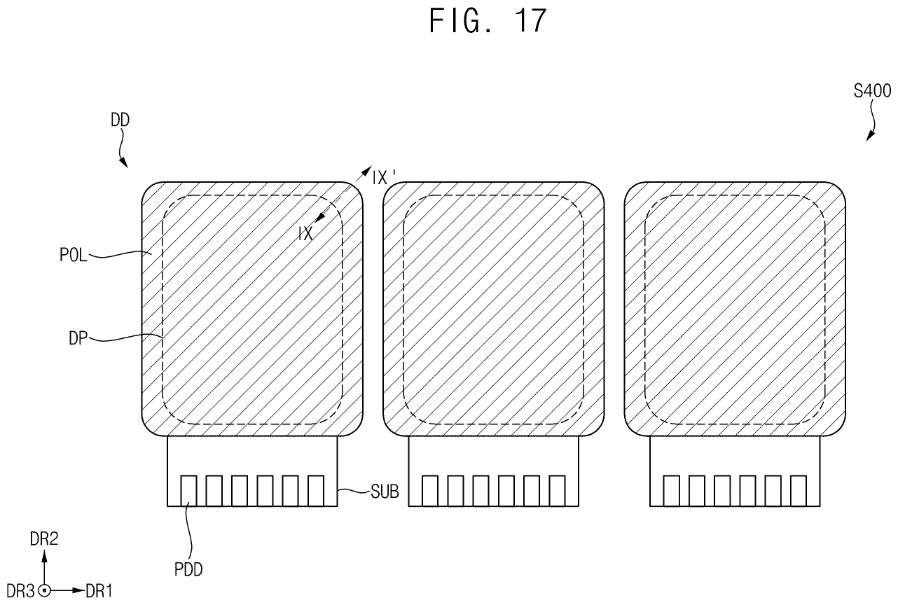

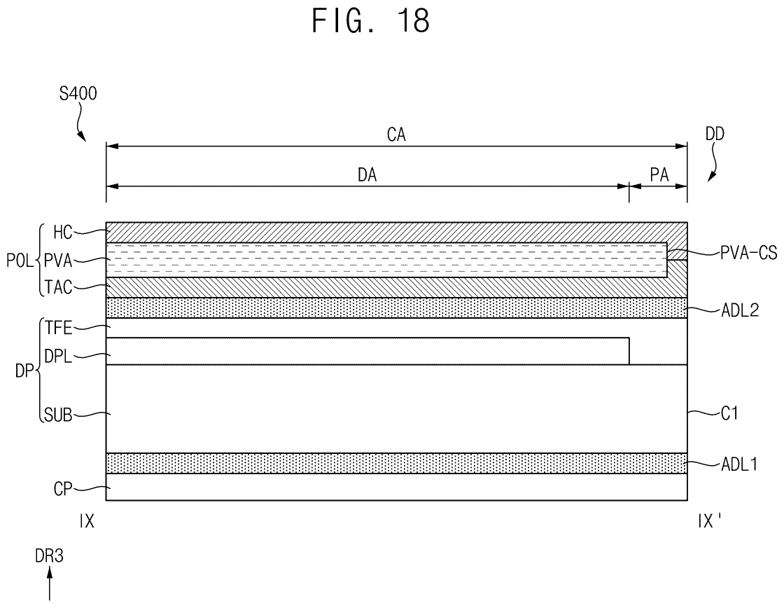

As illustrated in FIGS. 17 and 18, the intermediate polarization layer IPOL may be deformed by the second laser LAS2 to form the polarization layer POL. Specifically, the first preliminary functional layer PTAC, the preliminary polarization film PPVA, and the second preliminary functional layer PHC may be deformed by the second laser LAS2 to form the first functional layer TAC, the polarization film PVA, and the second functional layer HC, respectively.

The preliminary polarization film PPVA may include polyvinyl alcohol. In this case, the preliminary polarization film PPVA may shrink due to the thermal energy provided by the second laser LAS2. As a result, a side surface PPVA-S of the preliminary polarization film PPVA adjacent to the first edge of the substrate SUB that extends in a curved shape may shrink. As a result, in an area adjacent to or overlapping the first edge of the substrate SUB that extends in a curved shape in a plan view, the polarization film PVA may have the recessed side surface PVA-CS toward the central portion of the substrate SUB. In other words, in the area adjacent to or overlapping the first edge of the substrate SUB that extends in a curved shape in a plan view, the polarization film PVA may have the recessed side surface PVA-CS toward the central portion of the polarization layer POL.

Each of the first preliminary functional layer PTAC and the second preliminary functional layer PHC may include tri-acetyl cellulose. In this case, the first preliminary functional layer PTAC and the second preliminary functional layer PHC may expand due to the thermal energy provided by the second laser LAS2. Accordingly, a side surface PTAC-S of the first preliminary functional layer PTAC and a side surface PHC-S of the second preliminary functional layer PHC adjacent to the first edge of the substrate SUB that extends in a curved shape may expand. As a result, in the area adjacent to or overlapping the first edge of the substrate SUB that extends in a curved shape in a plan view, the first preliminary functional layer PTAC and the second preliminary functional layer PHC may extend to cover the depressed side surface PVA-CS of the polarization film PVA. Accordingly, in the area adjacent to or overlapping the first edge of the substrate SUB in a plan view, the first functional layer TAC and the second functional layer HC may cover the depressed side surface PVA-CS of the polarization film PVA, and the first functional layer TAC and the second functional layer HC may contact each other. In other words, the depressed side surface PVA-CS of the polarization film PVA may be sealed by the first functional layer TAC and the second functional layer HC.

Accordingly, in an area adjacent to or overlapping the second edge of the substrate SUB that extends in a straight line in a plan view, a side surface of the first functional layer TAC, a side surface of the polarization film PVA, and a side surface of the second functional layer HC may be substantially aligned along a thickness direction of the substrate SUB (e.g., the third direction DR3) may be substantially aligned along the thickness direction of the substrate (SUB), and in the area adjacent to or overlapping the first edge of the substrate SUB that extends in a curved shape in a plan view, the first functional layer TAC and the second functional layer HC may cover the recessed side surface PVA-CS of the polarization film PVA.

When a laser (e.g., the first laser LAS1 of FIG. 12) is irradiated to cut the preliminary polarization layer (PPOL, refer to FIG. 12), the energy density of the irradiated laser may be relatively greater at the first edge of the substrate SUB that extends in a curved shape than at the second edge of the substrate SUB that extends in a straight line. In this case, a problem of delamination of the preliminary polarization film PPVA, which is vulnerable to heat, may occur near the first edge of the substrate SUB that extends in a curved shape. In this case, moisture may penetrate into a portion where the preliminary polarization film PPVA is delaminated, and defects of the polarization layer POL due to moisture may occur.

According to the present disclosure, a process of irradiating the second laser LAS2 along the first edge of the substrate SUB that extends in a curved shape may be performed to provide thermal energy to the intermediate polarization layer IPOL where the cutting process has been performed. In this case, the second focus FP2 of the second laser LAS2 may be formed under the first focus FP1 of the first laser LAS1. When thermal energy is provided to the intermediate polarization layer IPOL, the preliminary polarization film PPVA may shrink, and each of the first preliminary functional layer PTAC and the second preliminary functional layer PHC may expand. Accordingly, the polarization film PVA may have the recessed side surface PVA-CS toward the central portion of the substrate SUB, and the first functional layer TAC and the second functional layer HC may cover the recessed side surface PVA-CS of the polarization film PVA. In other words, the first functional layer TAC and the second functional layer HC may seal the recessed side surface PVA-CS of the polarization film PVA. Accordingly, the first functional layer TAC and the second functional layer HC may prevent moisture from penetrating into the recessed side surface PVA-CS of the polarization film PVA. As a result, the defects of the polarization layer POL due to moisture may be suppressed, and the reliability of the polarization layer POL may be improved.

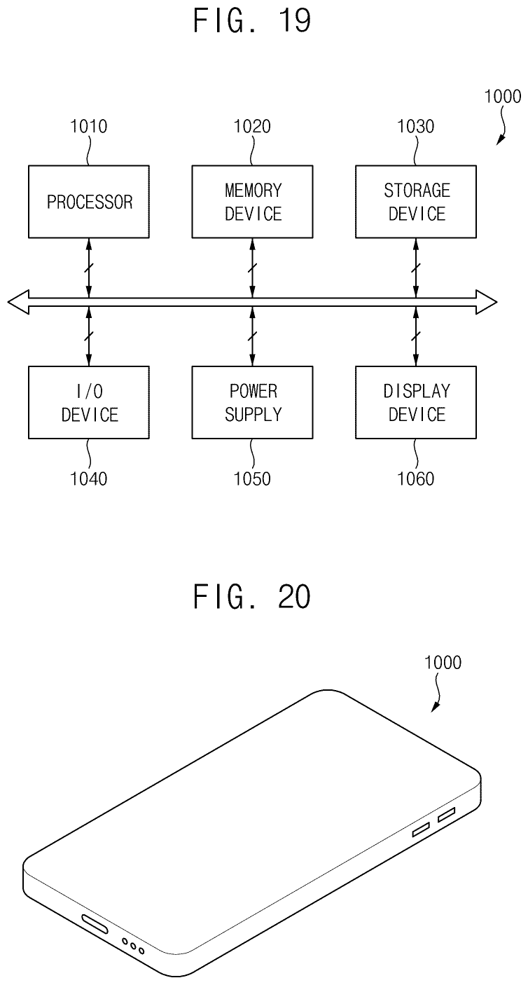

FIG. 19 is a block diagram illustrating an electronic device according to an embodiment of the present disclosure. FIG. 20 is a view illustrating an example in which the electronic device of FIG. 19 is implemented as a smart phone.

Referring to FIGS. 19 and 20, an electronic device 1000 may include a processor 1010, a memory device 1020, a storage device 1030, an input/output (I/O) device 1040, a power supply 1050, and a display device 1060. The display device 1060 may be the display device DD of FIG. 1. In addition, the electronic device 1000 may further include a plurality of ports for communicating with a video card, a sound card, a memory card, a universal serial bus (“USB”) device, other systems, and the like.

In an embodiment, as illustrated in FIG. 20, the electronic device 1000 may be implemented as a smart phone. However, the electronic device 1000 is not limited thereto. For example, the electronic device 1000 may be implemented as a smart pad, a smart watch, a tablet PC, a car navigation system, a computer monitor, a laptop, a head mounted display (“HMD”) device, and the like.

The processor 1010 may perform various computing functions. The processor 1010 may be a microprocessor, a central processing unit (“CPU”), an application processor (“AP”), and the like. The processor 1010 may be coupled to other components through an address bus, a control bus, a data bus, and the like. In an embodiment, the processor 1010 may be coupled to an extended bus such as a peripheral component interconnection (“PCI”) bus.

The memory device 1020 may store data for operations of the electronic device 1000. For example, the memory device 1020 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, and the like and/or at least one volatile memory device such as a dynamic random access memory (“DRAM”) device, a static random access memory (“SRAM”) device, a mobile DRAM device, and the like.

The storage device 1030 may include a solid-state drive (“SSD”) device, a hard disk drive (“HDD”) device, a CD-ROM device, and the like. The I/O device 1040 may include an input device such as a keyboard, a keypad, a mouse device, a touch-pad, a touch-screen, and the like, and an output device such as a printer, a speaker, and the like. In some embodiments, the I/O device 1040 may include the display device 1060.

The power supply 1050 may provide power for operations of the electronic device 1000. In other words, the power supply 1050 may provide power to the display device 1060. The display device 1060 may be connected to other components through buses or other communication links.

The present disclosure may be applied to various display devices. For example, the present disclosure is applicable to various display devices such as display devices for vehicles, ships and aircraft, portable communication devices, display devices for exhibition or information transmission, medical display devices, and the like.

The foregoing is illustrative of the embodiments of the present disclosure, and is not to be construed as limiting thereof. Although a few embodiments have been described with reference to the figures, those skilled in the art will readily appreciate that many variations and modifications may be made therein without departing from the spirit and scope of the present disclosure as defined in the appended claims.

What is claimed is:

1. A display device comprising:
a substrate having an edge comprising a first side extending in a first direction, a second side extending in a second direction intersecting the first direction, and a curved portion which connects the first side and the second side and has a predetermined curvature in a plan view;
a light-emitting element disposed on the substrate; and
a polarization layer disposed on the light-emitting element and comprising:
a polarization film disposed on the light-emitting element and having a side surface which is recessed from a side surface of the polarization layer in the curved portion in the plan view;
a first functional layer disposed between the light-emitting element and the polarization film and covering the recessed side surface of the polarization film in the curved portion in the plan view; and
a second functional layer disposed on the polarization film, covering the recessed side surface of the polarization film, and contacting the first functional layer in the curved portion in the plan view.

2. The display device of claim 1,
wherein the polarization film includes a polyvinyl alcohol, and
wherein each of the first functional layer and the second functional layer includes a tri-acetyl cellulose.

3. The display device of claim 1, wherein each of the first side and the second side extends in a substantially straight line.

4. The display device of claim 3, wherein, in the first side and the second side, a side surface of the first functional layer, a side surface of the polarization film, and a side surface of the second functional layer are substantially aligned along a thickness direction of the substrate in the plan view.

5. The display device of claim 4, wherein, in the first side and the second side, the first functional layer is spaced apart from the second functional layer.

6. A method of manufacturing a display device, the method comprising:
forming a light-emitting element on a mother substrate comprising a cell area and a dummy area surrounding the cell area, the light-emitting element overlapping the cell area;
forming a preliminary polarization layer overlapping the cell area and the dummy area on the light-emitting element, the preliminary polarization layer comprising a first preliminary functional layer, a preliminary polarization film, and a second preliminary functional layer which are sequentially stacked;
irradiating a first laser along edges of the cell area toward the mother substrate to form a substrate by removing a portion of the mother substrate and a portion of the preliminary polarization layer in the dummy area; and
irradiating a second laser along a first edge of the substrate having a curved shape to form a polarization film having a recessed side surface by deforming the preliminary polarization film in the first edge of the substrate in a plan view and form a first functional layer and a second function layer covering the recessed side surface by deforming the first preliminary functional layer and the second preliminary functional layer in the first edge of the substrate in the plan view.

7. The method of claim 6, wherein a first depth of focus of the first laser is formed at the mother substrate.

8. The method of claim 6, wherein the portion of the mother substrate and the portion of the preliminary polarization layer are simultaneously cut by the first laser.

9. The method of claim 6, wherein the preliminary polarization film, the first preliminary functional layer, and the second preliminary functional layer are deformed by thermal energy provided by the second laser.

10. The method of claim 9, wherein, in the deforming the preliminary polarization film, the first preliminary functional layer, and the second preliminary functional layer, the preliminary polarization film shrinks, and each of the first preliminary functional layer and the second preliminary functional layer expands.

11. The method of claim 6, wherein the substrate and the preliminary polarization layer are not cut by the second laser.

12. The method of claim 6, wherein a second depth of focus of the second laser is different from a first depth of focus of the first laser.

13. The method of claim 12, wherein the second depth of focus of the second laser is longer than the first depth of focus of the first laser.

14. The method of claim 12, wherein the second depth of focus of the second laser is shorter than the first depth of focus of the first laser.

15. The method of claim 12, wherein a distance between the first depth of focus and the second depth of focus is about 500 micrometers to about 2 millimeters.

16. The method of claim 6, wherein a second depth of focus of the second laser is formed under the substrate.

17. The method of claim 16, wherein a distance between the second depth of focus and a lower surface of the first preliminary functional layer is about 500 micrometers to about 2 millimeters.

18. The method of claim 6, wherein, in a second edge of the substrate having a straight line shape in the plan view, a side surface of the first functional layer, a side surface of the polarization film, and a side surface of the second functional layer are substantially aligned along a line extending in a thickness direction of the substrate.

19. The method of claim 18, wherein, in the second edge of the substrate in the plan view, the first functional layer is spaced apart from the second functional layer.

20. An electronic device comprising:
a display device comprising a light-emitting element; and
a power supply configured to provide power to the display device,
wherein the display device comprises:
a substrate having an edge comprising a first side extending in a first direction, a second side extending in a second direction intersecting the first direction, and a curved portion which connects the first side and the second side and has a predetermined curvature in a plan view;
the light-emitting element disposed on the substrate; and
a polarization layer disposed on the light-emitting element and comprising:
a polarization film disposed on the light-emitting element and having a side surface which is recessed from a side surface of the polarization layer in the curved portion in the plan view;
a first functional layer disposed between the light-emitting element and the polarization film and covering the recessed side surface of the polarization film in the curved portion in the plan view; and
a second functional layer disposed on the polarization film, covering the recessed side surface of the polarization film, and contacting the first functional layer in the curved portion in the plan view.
